(19) United States
(12) Patent Application Publication
(10) Pub. No.: US 2017/0332491 A1
(43) Pub. Date: Nov. 16, 2017

(54) LOW-WARPAGE CERAMIC CARRIER PLATE AND METHOD FOR PRODUCTION

(71) Applicant: SNAPTRACK, INC., San Diego, CA (US)

(72) Inventors: Yasuharu MIYAUCHI, Graz (AT); Pavol DUDESEK, Bad Gams (AT); Edmund PAYR, Graz (AT); Günther PUDMICH, Köflach (AT)

(21) Appl. No.: 15/531,361

(22) PCT Filed: Dec. 15, 2015
(86) PCT No.: PCT/EP2015/079813

§ 371 Date: May 26, 2017

(30) Foreign Application Priority Data
Dec. 16, 2014 (DE) 102014118749.0

(51) Int. Cl. H05K 1/16; H05K 3/00; H05K 1/03; H05K 1/02; H01G 4/30; H01G 4/12; H05K 3/46; H01C 7/105

(52) U.S. Cl. CPC H05K 1/162; H05K 3/4644; H05K 3/0044; H05K 1/167; H01C 7/105; H05K 1/0271; H01G 4/30; H01G 4/12; H05K 1/0306

(57) ABSTRACT

For a carrier plate, it is proposed to brace a first ceramic functional layer over a connecting layer (VS) with a ceramic stressing layer (SPS) in order to reduce the lateral sintering shrinkage. The functional layer (FS) and the stressing layer (SPS) are glass-free or have only a small glass content of less than 5 wt %, whereas the connecting layer (VS) comprises a glass component or is a glass layer.

The invention relates to a ceramic carrier plate that may comprise a passive component integrated therein, and that may serve as a substrate for mounting an electrical component. The invention furthermore relates to a method for production of the carrier plate.

Known ceramic carrier plates have at least one functional layer that comprises a functional ceramic in which an electrical component is realized or may be realized. Such functional ceramics may be selected from varistor ceramics or other electroceramics such as ferrite, piezoelectric ceramics, thermistor materials (selected from NTC and PTC), dielectric ceramics for multilayer capacitors (MLCC), LTCC ceramics (MCM), and others.

The carrier plates are manufactured via sintering of green compact which already comprises structured electrodes or green structured electrode layers. To maintain the structural precision of electrodes and interfaces, it is therefore advantageous if the green compact exhibits only slight lateral shrinkage upon sintering.

Various possibilities to reduce the lateral shrinkage are known. One possibility is to exert a force orthogonally to the layer plane on the green compact during the sintering, in order to predominantly force the shrinkage in this direction. An additional possibility is to provide a stressing layer that is bonded with the green compact for the functional ceramic, which stressing layer reduces the lateral shrinkage upon sintering due to an adhesion effect with the green compact. The stressing layer remains an integral part of the carrier plate after the sintering process.

However, it is also possible to execute the stressing layer as a sacrificial layer that is sintered with the green compact and is removed from the substrate after the sintering process.

For the second and third methods, it is especially important that a sufficiently strong bond is generated between the stressing layer and the functional layer or the green compact, which, however, is difficult to achieve due to the different ceramics.

Known methods use stressing layers and/or functional layers that contain a glass content of more than 5%, at least on the surface. The bonding of the unsintered stressing layer with the later functional ceramic is only ensured by the glass content. If the glass content in the layer regions on both sides of the connecting layer is chosen to be less than 5 wt %, for example, the bonding of the layers during sintering is not ensured, and delamination of both layers, and as a result substrate deformations regularly occur, which altogether cause an increased rejection in manufacturing.

However, the glass admixing is disadvantageous in that this produces a degradation of the electrical or dielectrical properties of the functional ceramic. On the one hand, this is to be ascribed to the impure (because it contains glass) functional layer that may unacceptably strongly degrade the function of the functional ceramics. Moreover, some glass components may diffuse and produce a chemical alteration of the layer of the functional ceramics, which likewise results in a degradation.

If a permanent stressing layer is used, consequently manufactured ceramics or a manufactured crystal onto which the green compact is applied for the functional layer, in some instances it is possible to find material combinations that have good bonding with one another. However, the possible material combinations are very limited in number, and not all functional layers can be braced in this way.

It is therefore an object of the present invention to specify a carrier plate whose stressing layer and functional layer bond well to one another and thus exhibit a strongly reduced lateral shrinkage after sintering. It should be possible for the good adhesion of stressing layer and functional layer to take place without degradation of the electrical or dielectrical properties of the functional layers. An additional object is to specify a method to manufacture the carrier plate.

This object is achieved according to the invention by a carrier plate circuit having the features of claim 1. Additional advantageous embodiments of the invention, as well as a method for manufacturing the carrier plate, are to be learned from additional claims.

The invention solves the problem of adhesion between functional layer and stressing layer with the aid of a connecting layer arranged between them. Functional layer and stressing layer are formed free of glass or have only a small glass content of less than 5 wt %, which normally does not yet produce degradation of the electrical properties of the functional layer or of the functional ceramic present in the functional layer. The connecting layer is itself a glass layer or comprises glass-forming components (also designated as glass components in the following) such as oxides that transform into glass in a sintering process.

Such a carrier plate may be produced with only slight lateral sintering shrinkage and little warpage since the connecting layer ensures good bonding between functional layer and stressing layer. The carrier plate according to the invention has the advantage that the electrical properties of the functional layer are not affected by the connecting layer, and therefore are also not degraded.

The connecting layer has a layer thickness of approximately 0.5 to 10 μm. With this relatively small layer thickness, it is already guaranteed that the glass component may also completely surround the ceramic grains of both layers, even given a coarse surface structure of functional layer and/or stressing layer. This ensures a maximum common surface (interface), and therefore maximum bonding.

The connecting layer furthermore has a matched coefficient of thermal expansion that preferably is between that of the stressing layer and that of the functional layer. If the stressing layer is used as a sacrificial layer and is removed again later, the coefficient of thermal expansion of the connecting layer is advantageously chosen to be less than or equal to the expansion coefficient of the functional layer.

Both the flow characteristic and the coefficient of thermal expansion of the connecting layer may be adjusted via addition of selected filler particles. For example, advantageous fillers may be selected from the same material as the stressing layer. This ensures a good adaptation to the coefficients of expansion of the functional layer or of the stressing layer. Fillers may also serve for the adjustment of other physical properties of the connecting layer.

The glass component or glass components are present in the connecting layer as fine glass particles or as glass-forming oxides before the sintering. Furthermore, the connecting layer is preferably free of mobile ions that diffuse into the functional layer and possibly might cause a degradation of its properties. This is particularly to be kept in mind if the functional layer consists ofvaristor ceramics, and especially if it is doped with praseodymium.

The melting point of the connecting layer may be in the range of that of the functional layer, but normally is lower than the melting point of the functional layer. However, too great a difference in melting point is disadvantageous.

Furthermore, the connecting layer is made of a material which flows in a controlled manner during the sintering process. For a sufficiently good adhesion effect, it is also not necessary that the connecting layer completely wets the surfaces of the stressing layer and the functional layer. The wetting property may therefore be reduced without the adhesion thereby being too strongly reduced.

The connecting layer preferably contains glass components for a borosilicate glass which is characterized by a low coefficient of thermal expansion CTE and has elastoplastic properties. The latter makes it possible that no excessive thermal warping develops within the connecting layer upon cooling. The glass components therefore preferably have oxides of silicon and/or germanium, boron and potassium, or other alkali metals, as primary components. The glass components of the connecting layer may be selected exclusively from the cited ions and oxides. However, other ions are likewise possible insofar as they do not unacceptably change the properties of the borosilicate glass, and thereby also do not degrade the electrical properties of the functional ceramic.

The cited primary components comprise at least 70 wt % of the connecting layer. In addition to these, solid final sintering fillers may form the content up to 100 wt %. With such a glass content or glass component content, and such an upper limit for the filler content, the connecting layer may guarantee a good mechanical connection between the stressing layer and the functional layer.

If the carrier plate comprises varistor ceramics that is especially sensitive to diffusion of specific ions and whose electrical properties could thereupon degrade, the connecting layer or the glasses and glass components used for this are essentially free of aluminum, gallium, chromium and titanium. However, under the circumstances an aluminum content is also allowable insofar as the sintering temperature of the functional layer is below the diffusion temperature at which a diffusion of the aluminum into the functional ceramic may take place, especially if this is selected from a varistor material. However, for co-firing processes, especially given LTCC ceramics, aluminum is less suitable.

If the functional layer is a different layer than varistor ceramics, and especially is a different semiconductor, other ions may thus be harmful to their electrical function and are advantageously avoided as part of the intermediate layer or of the glasses and glass components used for these.

The functional ceramics may be a ferrite, NTC ceramics or PTC ceramics.

The stressing layer has a sintering temperature that is markedly above the sintering temperature of the functional layer and the connecting layer. This enables a sintering method in which the structure of the stressing layer remains unchanged, and this may deploy its effect as a stressing layer for the functional layer upon sintering, and especially after cooling.

The stressing layer may consist of solid, consequently dense, ceramics. In this instance, a good mutual adaptation of the different coefficients of thermal expansion is greatly advantageous. However, the stressing layer may also be a non-sintering powder layer from which only the binder is burnt off. Such layers also exhibit a high mechanical strength that enables their use as a stressing layer. The mechanical strength is ascribed to Van der Waals forces.

An advantageous selection of materials for the stressing layer are therefore cost-effective, final sintering materials having low coefficients of thermal expansion.

Examples of good suitable materials are final sintering oxides and other compounds such as, for example, zirconium oxide, magnesium oxide, strontium carbonate, barium carbonate or magnesium silicate. Further suitable materials are also nitrides, carbides and borides that, however, are not always cost-effective. Aluminum oxide ceramics as a stressing layer are just as suitable as other refractor materials.

For the stressing layer, a layer thickness is chosen that approximately corresponds to the layer thickness of the functional layer. What is understood by the thickness of the functional layer is the thickness of all partial layers of the functional layer that, in addition to layers made of functional ceramics, may further comprise metallization layers for electrodes and other auxiliary and intermediate layers. The layer thickness of the stressing layer should be selected so that it corresponds to at least half of the layer thickness of the functional layer.

However, it is also possible to provide two stressing layers in the carrier plate according to the invention, which two stressing layers are arranged on opposite sides of the functional layer and are respectively applied with a connecting layer as an intermediate layer. In the dimensioning of the thickness of the two stressing layers, the sum of the layer thicknesses of both stressing layers is considered, which then is ideally between 50 and 100% of the layer thickness of the functional layer.

The functional layer may comprise a varistor material in which a varistor is formed. In addition to a functional ceramics layer made of varistor material, this comprises at least two electrode layers, but preferably a multi-layer structure in which multiple partial layers of the varistor ceramics alternate with structured electrode layers in said multi-layer structure.

Other passive components may also be realized in the functional layer. Ceramic multi-layer capacitors (MLCC) likewise have a multi-layer structure in which alternating electrode layers and functional ceramic layers provide the component function.

The functional layer may also have feedthroughs via which either different metallization layers are connected with one another, or given which deeper-lying electrode layers may be connected with the surface of the functional layer. A terminal for these deeper-lying functional layers to the surface of the functional layer may be achieved with the aid of feedthroughs.

The functional layer may moreover comprise at least two partial layers of functional ceramics that have different electroceramic properties, that together have at least three metallization layers, and that are structured with the aid of electrodes to form two different passive electrical components. At least one respective passive component is preferably realized within a partial layer of functional ceramic.

The invention will be explained in greater detail below with reference to exemplary embodiments and the accompanying figures. The Figures serve to illustrate the invention, therefore are depicted only schematically and not true to scale. Therefore, absolute or even only relative dimensions are not to be learned from Figures.

### BRIEF DESCRIPTION OF THE DRAWINGS

FIG. 1 shows a first carrier plate in schematic cross section,

FIG. 2 shows a second carrier plate in schematic cross section,

FIG. 3 shows a detail from FIG. 1 or 2,

FIGS. 4A through 4D show various method stages in the manufacturing of a carrier plate according to a first embodiment,

FIGS. 5A through 5C show various method stages in the manufacturing of a carrier plate according to a second embodiment,

FIG. 6 shows a functional layer having an exemplary passive component integrated therein, in schematic cross section,

FIG. 7 shows the functional layer of FIG. 6 after sintering, with remaining connecting layer,

FIG. 8 shows the functional layer of FIG. 7 after the application of electrical terminal surfaces,

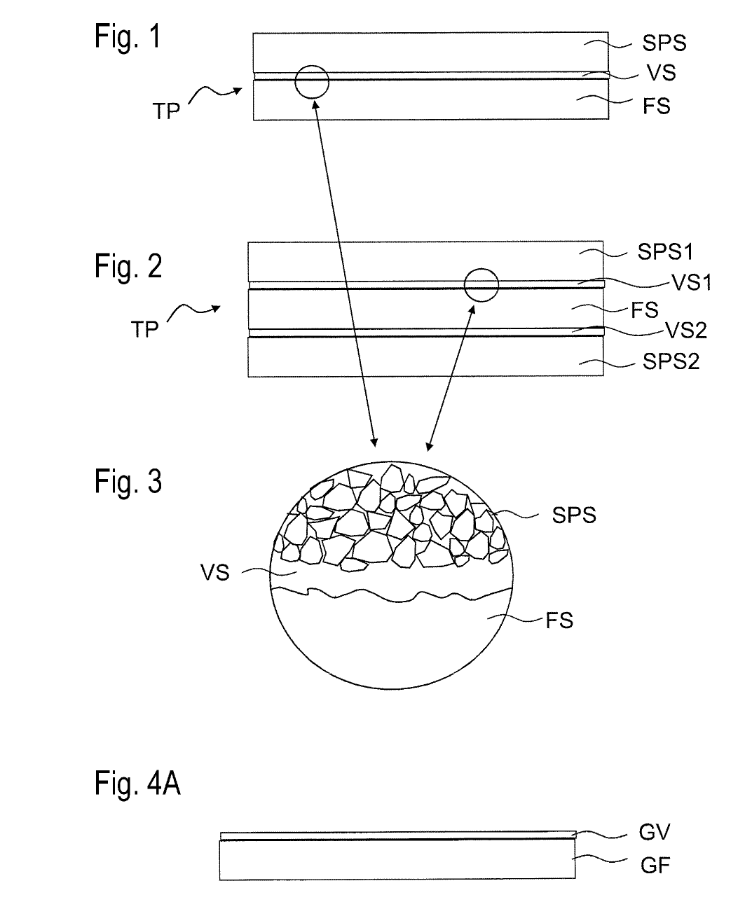

FIG. 1 shows a simple embodiment of a carrier plate according to the invention, in which a stressing layer SPS is installed over a first functional layer FS by means of a connecting layer VS. For example, the functional layer FS comprises a functional ceramic based on a varistor ceramics, with a varistor formed therein.

For the connecting layer VS, a glass composition is prepared having 78 wt % SiO2, 19 wt % boric oxide, 3 wt % potassium oxide. Such a composition is matched with regard to the coefficient of expansion to the material of the varistor ceramics. The transition temperature of the glass is approximately 775°.

For example, the connecting layer VS is applied (via printing, for example) onto the functional layer FS in the form of a paste that comprises the cited glass components in finely distributed form. The layer thickness of the highly viscous connecting layer VS is approximately 2 to 10 μm.

For example, a green tape based on zirconium oxide is manufactured for the stressing layer SPS. The green tape is laminated onto the connecting layer VS over the functional layer FS.

The complete structure is subsequently sintered at 920° C. At this temperature, the glass component in the connecting layer VS melts and flows. Only the binder thereby burns off in the green tape for the stressing layer SPS, whereas the grain structure of the stressing layer SPS remains largely maintained without volume shrinkage. Nevertheless, the grains preserve a high strength among one another that is sufficient to achieve the bracing effect during the sintering of the carrier plate or of the structure. After controlled cooling to room temperature, the structure depicted in FIG. 1 is obtained.

The structure depicted in FIG. 1 may now serve as a substrate for an electrical component. However, it is also possible to remove the stressing layer SPS (which has a grained structure) again before the further processing to form the substrate. Mechanical removal methods lend themselves to this, for example sandblasting with a suitable particulate medium (for example with zirconium oxide grains), wet abrasion with abrasive articles or brushes. Abrasive brushing may be implemented in multiple stages, wherein brushes of different hardness are used in a series of sub-steps so that the abrasive brushing takes place with the softest brush in the last method step.

The dimensions of the functional layer are determined before and after the sintering, and the lateral shrinkage is thus ascertained. It has been shown that the carrier plate according to the invention exhibits a lateral shrinkage of less than 1.0%, measured along the x/y axes. Shrinkage beyond this is prevented by the stressing layer.

FIG. 2 shows a further embodiment of a carrier plate TP according to the invention, in which a second stressing layer SPS2 is applied opposite the first stressing layer SPS1 by means of a second connecting layer VS2. The arrangement thus has a symmetrical structure with the functional layer FS as a mirror plane. The application of the second stressing layer takes place like the application of the first stressing layer. The two stressing layers SPS1, SPS2 are applied either synchronously or in continuous succession. The sintering step takes place together for both bracing layers.

FIG. 3 shows a structural detail of a carrier plate TP according to the invention at the interface between stressing layer SPS, connecting layer VS and functional layer FS. The functional layer FS is compacted via sintering and is free of pores. The surface has a certain residual roughness that is to be ascribed to the grain structure of the stressing layer SPS. By contrast to this, the stressing layer SPS has the particle structure from which the original binder present in the interstices is burnt off during the sintering process. The particles in the stressing layer SPS have agood bonding among one another, mechanically stabilize the stressing layer, and thus enable the bracing effect.

The connecting layer VS adapts to the two surfaces of functional layer FS and stressing layer SPS and generates a large adhesion effect due to the increased area of interfaces. The respective boundary layer between connecting layer VS and the respective surface of stressing layer SPS and functional layer FS is designated as an interface.

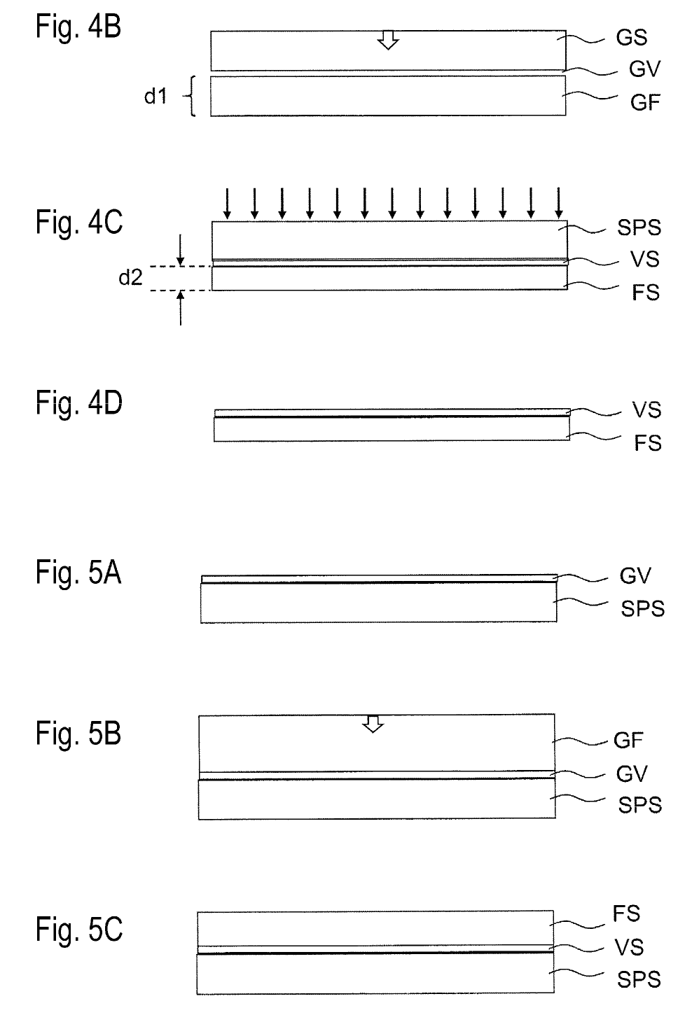

FIGS. 4A through 4D show various method stages in the manufacturing of a carrier plate according to a first embodiment. As a pre-stage of the connecting layer VS, a layer GV of a glass paste in a thin layer thickness up to a maximum of 10 μm is applied onto the green body GF of a functional layer FS. FIG. 4 shows the arrangement. A stressing layer SPS is now applied onto the layer GV, for example by laminating on a green tape GS that comprises a dense arrangement of final sintering ceramic particles (based on zirconium oxide, for example) in a binder.

The structure is subsequently sintered, wherein the green tape GS of the stressing layer SPS largely retains its volume since only the binder burns off. The glass paste layer GV of the connecting layer VS softens and flows on the porous surface of the stressing layer SPS.

The green tape structure GF of the functional layer FS is subsequently sintered and thereby generates a sintering shrinkage due to compaction. However, this appears only in a reduction of the layer thickness at the transition from the green tape structure GF to the functional layer FS. The layer thickness reduces from the original d1 according to FIG. 4B to d2 according to FIG. 4C. The lateral shrinkage is prevented by the bracing with the stressing layer SPS. Upon cooling after the sintering, the structure remains largely form-stable and dimensionally stable and is reduced merely by the thermal expansion.

If the stressing layer SPS is used as a sacrificial layer, it must subsequently be mechanically removed, as is indicated by arrows in FIG. 4C.

FIG. 4D shows the arrangement after the removal of the stressing layer. The functional layer FS is now still covered only by a glass layer that corresponds to the original connecting layer VS. Due to the greater hardness of the glass layer or of the connecting layer, this is mechanically stable versus the chosen removal method.

FIGS. 5A through 5C show various method stages in the manufacturing of a carrier plate according to a second embodiment. Here a stressing layer SPS present as a solid plate is assumed, onto which a glass paste GV for the connecting layer VS is applied in a thinner layer thickness, up to a maximum of 10 μm. FIG. 5A shows the arrangement at this method stage.

A green tape GF or a green tape stack for the functional layer FS is now applied onto the layer GV of the glass particles, for example by being laminated on. However, it is also possible to individually laminate on the green tapes for the functional layer. FIG. 5B shows the arrangement at this method stage, with laminated green tapes for the functional layer FS.

In the next step, the sintering takes place similarly to as is described using FIGS. 4A through 4D. Here as well, upon sintering and cooling the bracing of the functional layer FS with the stressing layer SPS prevents a lateral sintering shrinkage, such that the sintering shrinkage occurs exclusively in the dimension vertical to the layer plane. By contrast, the layer thickness of the tape stack for the functional layer FS or of the individual functional layers FS reduces, as is visible in comparison to FIGS. 5B and 5C.

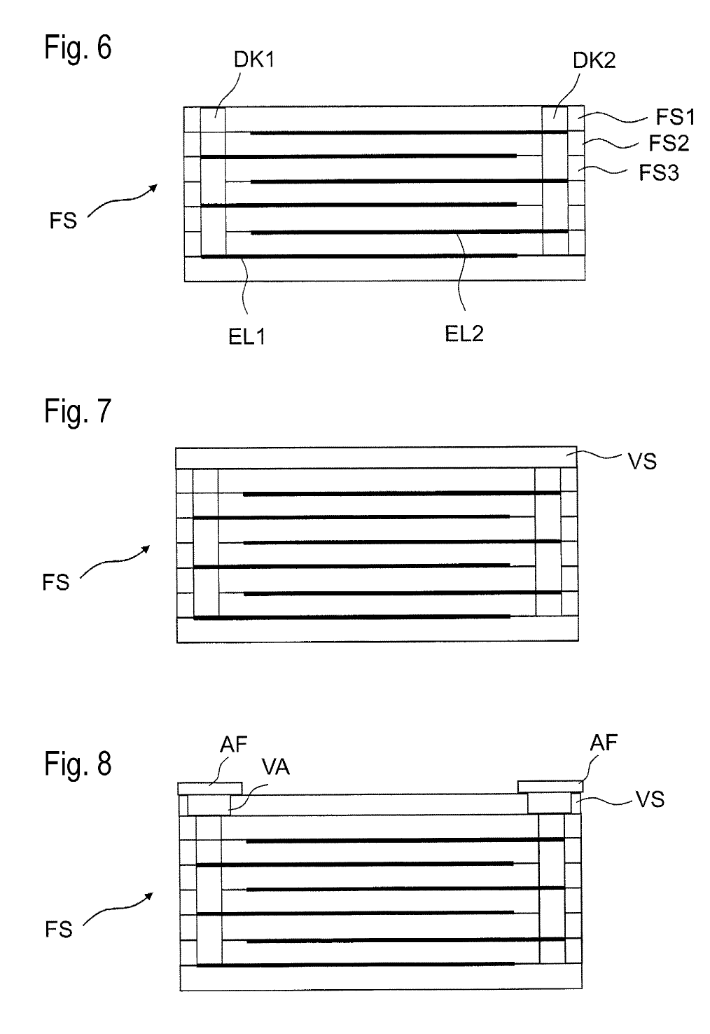

FIG. 6 shows an example of a passive component as it may be integrated into the stack of green tapes GF for the later functional layer FS. Arranged between two respective partial layers FS1, FS2, . . . of the functional ceramic is a respective structured electrode layer EL for the passive component. The electrode layers EL are alternately connected with a respective one of at least two feedthroughs DK1, DK2 so that first electrode layers EL1 are connected with a first feedthrough DK1, by contrast to which second electrode layers EL2 are connected with a second feedthrough DK2. Such an component structure may be realized with a varistor ceramic, for example, and thereby forms a varistor. This represents a protective component that conducts or discharges a current from first electrode to second electrode only as of an adjustable threshold voltage. If this threshold voltage is less than the overvoltage, the voltage may in this way be safely discharged upon reaching the threshold voltage.

However, the structure shown in FIG. 6 may also be a ceramic multi-layer capacitor in which the partial layers of the ceramic functional layer FS are executed from a dielectric. By applying a voltage between first and second electrode layer EL1, EL2, a capacitance forms between these two electrodes.

FIG. 7 shows the passive component depicted in FIG. 6 as a method product after sintering and the removal of the stressing layer. Only the glass layer of the original bracing layer VS is now still present over the functional layer FS.

In a single- or multi-stage process, a terminal surface AF may then be generated over the exposed upper ends of the feedthroughs DK and, in the adjacent edge region, on the surface of the glass layer of the original connecting layer VS. In a first sub-step, for this a via VA may be directed through the glass layer of the original connecting layer VS, for example via currentless metal deposition. The metallic electric terminal surface AF is subsequently generated over the filled via VA, for example via printing and firing of contacts. However, it is also possible to galvanically apply the contacts. FIG. 8 shows the arrangement at this method stage.

An electrical component may now be electrically and mechanically mounted on the terminal surfaces AF, wherein the carrier plate serves as a carrier for the component. Via the integrated passive component, a protective function may be realized in the carrier plate that protects the component from overvoltage, for example. However, other passive component functions may also be realized in the carrier plate in the form of corresponding passive components, and be connected with said component.

The invention [sic] explained using a few selected exemplary embodiments, and therefore is not limited to the presented embodiments and/or Figures. The invention is defined solely by the claims and encompasses additional variations within this scope. Sub-combinations of features of the claims are also considered to be according to the invention.

### LIST OF REFERENCE SIGNS

| | |
|---|---|
| TP | carrier plate |
| FS | ceramic functional layer (s) |
| SPS | ceramic stressing layer |
| VS | connecting layer |
| GV | glass paste layer for connecting layer |
| CTE | coefficient of thermal expansion |
| GF | green compact for a ceramic functional layer |
| GS | green compact for a ceramic stressing layer |
| FS1, FS2 | partial layers of the functional layer |
| GS | green tape for stressing layer |
| AF | electrical terminal surface |
| VA | via through connecting layer |

1. Carrier plate for an electrical component,
having a first ceramic functional layer
having a connecting layer (VS)
having a ceramic stressing layer (SPS) in which
the ceramic functional layer (FS) is connected via the connecting layer (VS) with the ceramic stressing layer (SPS) to form a carrier plate (TP)
a passive electrical component that can be connected with the electrical component is integrated into the ceramic functional layer (FS)
the functional layer (FS) and the stressing layer (SPS) are glass-free or have only a small glass content of less than 5 wt %
the connecting layer (VS) comprises a glass component or is a glass layer.

2. Carrier plate according to claim 1,
in which the thickness of the connecting layer (VS) is 0.5-10 μm.

3. Carrier plate according to claim 1 or 2,
in which the connecting layer (VS) also contains a non-sintering ceramic filler in addition to the glass component.

4. Carrier plate according to one of the claims 1-3,
in which the stressing layer (SPS) has a sintering temperature that is above the sintering temperatures of the functional layer (FS) and the connecting layer (VS).

5. Carrier plate according to one of the claims 1-4,
in which the stressing layer (SPS) has a relatively low coefficient of thermal expansion CTE that is smaller than the coefficient of thermal expansion CTE_{F} of the functional layer (FS).

6. Carrier plate according to one of the claims 1-5, having a second connecting layer (VS2) and a second stressing layer (SPS2), wherein the second stressing layer is connected via the second connecting layer with that surface of the functional layer (FS) that faces away from the first stressing layer, such that the carrier plate has a symmetrical structure with regard to layer sequence, materials and layer thicknesses.

7. Carrier plate according to one of the claims 1-6,
in which the at least one connecting layer (VS) comprises oxides of Si and/or Ge, B and K as primary components that, in total, comprise at least 70 wt % of the connecting layer, wherein the content up to 100 wt % in the connecting layer is formed by final sintering fillers.

8. Carrier plate according to one of the claims 1-7,
in which the functional layer (FS) comprises a layer made from a varistor material and has at least two electrode layers (EL1, EL2).

9. Carrier plate according to one of the claims 1-7,
in which the functional layer (FS) is selected from a layer of an NTC or PTC ceramic, a ceramic multi-layer capacitor, a ferrite layer, a piezoelectric layer, and an LTCC ceramic.

10. Carrier plate according to one of the claim 8 or 9,
in which the functional layer (FS) has at least two different partial layers (FS1, FS2) having different electroceramic properties, and at least three metallization layers which are structured for different passive electrical components, wherein the different passive components are integrated into the functional layer.

11. Carrier plate according to one of the claims 1-10,
in which the stressing layer (SPS) is a layer based on final sintering oxides and compounds such as ZrO₂, MgO, SrCO₃, BaCO₃ or MgSiO₄.

12. Method to manufacture a carrier plate according to claim 1, comprising the steps:
a) provision of a green compact for a ceramic functional layer in which a passive electrical component is preformed
b) application of a relatively thin layer of glass particles onto the green compact
c) application of a green compact for a ceramic stressing layer onto the glass particles
d) sintering of the structure at a temperature above the sintering temperature of the glass particles and of the ceramic functional layer
e) controlled cooling of the structure, wherein a permanent bond with a 1-10 μm thick glass layer is created, and the lateral sintering shrinkage is limited to a value of less than 3% per axis.

13. Method according to claim 12,
in which the green compact for the ceramic functional layer comprises at least one green tape in which the layer of glass particles is applied in the form of a paste onto the at least one green tape, in which a paste or a green tape is applied onto the layer of glass particles as a green compact for the ceramic stressing layer.

14. Method for manufacturing a carrier plate according to claim 1, having the alternative steps:
A) provision of a solid ceramic plate for a stressing layer (SPS),
B) application of a relatively thin layer (GV) of glass particles onto the stressing layer
C) application of a green compact for a ceramic functional layer (GF) onto the layer (GV) of glass particles, and preforming of a passive electrical component therein
d) sintering of the structure at a temperature that is above the sintering temperature of the glass particles and of the ceramic functional layer,
e) controlled cooling of the structure, wherein a permanent bond with a 1-10 μm thick glass layer VS is created, and the lateral sintering shrinkage is limited to a value of less than 3% per axis.

15. Method according to claims 1-14,
additionally including the step
f) implementation of a mechanical removal method after the cooling, in which the stressing layer (SPS) is removed again.

16. Method according to claim 15,
in which sandblasting, brushing or abrasion are used as a removal method.

17. Method according to one of the claims 12-16,
in which, after step E) or e), the uppermost contacts of the passive components under the glass layer in the permanent composite are revealed,
in which electrical terminal surfaces for an electrical component are applied onto the composite in electrically conductive contact with the uppermost contacts.
